(19) United States
(12) Patent Application Publication
(10) Pub. No.: US 2021/0336185 A1
(43) Pub. Date: Oct. 28, 2021

(54) DISPLAY PANEL AND MANUFACTURING METHOD THEREOF

(71) Applicant: TCL China Star Optoelectronics Technology CO., Ltd, Shenzhen, Guangdong (CN)

(72) Inventor: Guojie WANG, Shenzhen, Guangdong (CN)

(73) Assignee: TCL CHINA STAR OPTOELECTRONICS TECHNOLOGY CO., LTD., Shenzhen, Guangdong (CN)

(21) Appl. No.: 16/960,773

(22) PCT Filed: May 19, 2020
(86) PCT No.: PCT/CN2020/091073

§ 371 Date: Jul. 8, 2020

(30) Foreign Application Priority Data
Apr. 22, 2020 (CN) 202010321391.2

(51) Int. Cl. H01L 51/52; H01L 27/32; H01L 51/56

(52) U.S. Cl. CPC H01L 51/5209; H01L 27/3246; H01L 2227/323; H01L 51/56; H01L 27/3258

(57) ABSTRACT

A display panel and a manufacturing thereof are provided. The display panel includes: a first substrate; a thin film transistor (TFT) array layer and a planarization layer sequentially disposed on a surface of a side of the first substrate; an anode layer disposed on a surface of a side of the planarization layer; and a pixel defining layer. A plurality of pixel openings are formed on the anode layer. The anode layer includes a plurality of first anodes and a plurality of second anodes, which are spaced apart from each other.

### FIELD

The present disclosure relates to the field of display technologies, and more specifically, relates to a display panel and a manufacturing method thereof.

### BACKGROUND

Due to having advantages such as self-luminescence, wide viewing angles, high contrast, fast response times, and a light and thin body, organic light-emitting diode (OLED) devices have become a mainstream among display technologies.

Compared with OLED devices manufactured using a fine metal mask (FMM) or vacuum evaporation, OLED devices manufactured by inkjet printing can achieve precise alignment without using the FMM and can achieve 100% material usage. Therefore, they have attracted attention from people and have become a trend in manufacturing large-scale OLED devices.

Typically, a pixel arrangement structure of OLEDs is composed of a plurality of pixel dots. Each of the pixel dots includes a red sub-pixel, a green sub-pixel, and a blue sub-pixel, and the red sub-pixels, the green sub-pixels, and the blue sub-pixels in all of the pixel dots are arranged regularly to form a matrix. However, the above conventional pixel arrangement structure has following problems: first, during a printing process, a size of ink dropped in pixels may be overly large or overly small because printhead nozzles are not stable. As a result, several light lines or dark lines may appear on an image displayed by products, resulting in line Mura. Second, only printhead nozzles corresponding to the pixels eject ink, and printhead nozzles corresponding to areas between the pixels do not eject ink, contributing to low usage of the printhead nozzles. Consequently, the printing process needs to be repeated many times, resulting in long printing times. Furthermore, ink printed at different periods cannot be evenly dried, resulting in dry Mura.

Regarding the technical problems: in conventional display panels, a size of ink dropped in pixels may be overly large or overly small, a printing process takes too much time, and the ink printed at different periods cannot be evenly dried, resulting in Mura problems.

### SUMMARY

An embodiment of the present disclosure provides a display panel and a manufacturing method thereof to solve following technical problems: in conventional display panels, a size of ink dropped in pixels may be overly large or overly small, a printing process takes too much time, and the ink printed at different periods cannot be evenly dried, resulting in Mura problems.

To solve the above problems, in a first aspect, the present disclosure provides a display panel, including:

a first substrate;

a thin film transistor (TFT) array layer and a planarization layer which are sequentially disposed on a surface of a side of the first substrate;

an anode layer disposed on a surface of a side of the planarization layer away from the TFT array layer; and

a pixel defining layer, wherein a plurality of pixel openings are formed on the anode layer; and

wherein the anode layer includes a plurality of first anodes and a plurality of second anodes, which are spaced apart from each other.

In some embodiments of the present disclosure, an insulating material is filled between the first anodes and the second anodes.

In some embodiments of the present disclosure, a distance between the first anodes and the second anodes ranges from 2 μm to 10 μm.

In some embodiments of the present disclosure, a length of long edges of the first anodes ranges from 100 μm to 200 μm, and a length of short edges of the first anodes ranges from 20 μm to 80 μm.

In some embodiments of the present disclosure, a first orthographic projection of the pixel defining layer on the first substrate includes at least two long edges and at least two short edges, and each of the short edges is connected to the at least two long edges.

In some embodiments of the present disclosure, a first orthographic projection of the pixel defining layer on the first substrate overlaps with at least a portion of a second orthographic projection of the anode layer on the first substrate.

In some embodiments of the present disclosure, the anode layer includes a hydrophilic material, or a hydrophilic thin film is disposed on the anode layer.

In some embodiments of the present disclosure, the display panel further includes an organic light-emitting diode (OLED) device including an anode layer, a hole injection layer, a hole transport layer, a luminescent layer, and a cathode layer.

In some embodiments of the present disclosure, a sectional view of the pixel defining layer is trapezoidal and has a narrow top and a wide bottom.

In a second aspect, the present disclosure provides a manufacturing method of the above display panel, including following steps:

sequentially forming a thin film transistor (TFT) array layer and a planarization layer on a surface of a side of a first substrate;

forming an anode layer on a surface of a side of the planarization layer away from the TFT array layer; and

forming a pixel defining layer with a plurality of pixel openings on the anode layer.

In some embodiments of the present disclosure, the anode layer includes a plurality of first anodes and a plurality of second anodes, which are spaced apart from each other.

In some embodiments of the present disclosure, an insulating material is filled between the first anodes and the second anodes.

In some embodiments of the present disclosure, a distance between the first anodes and the second anodes ranges from 2 μm to 10 μm.

In some embodiments of the present disclosure, a length of long edges of the first anodes ranges from 100 μm to 200 μm, and a length of short edges of the first anodes ranges from 20 μm to 80 μm.

In some embodiments of the present disclosure, a first orthographic projection of the pixel defining layer on the first substrate includes at least two long edges and at least two short edges, and each of the short edges is connected to the at least two long edges.

In some embodiments of the present disclosure, a first orthographic projection of the pixel defining layer on the first substrate overlaps with at least a portion of a second orthographic projection of the anode layer on the first substrate.

In some embodiments of the present disclosure, the anode layer includes a hydrophilic material, or a hydrophilic thin film is disposed on the anode layer.

In some embodiments of the present disclosure, the display panel further includes an organic light-emitting diode (OLED) device including an anode layer, a hole injection layer, a hole transport layer, a luminescent layer, and a cathode layer.

In some embodiments of the present disclosure, a sectional view of the pixel defining layer is trapezoidal and has a narrow top and a wide bottom.

Regarding the beneficial effects: compared with conventional display panels, an anode layer of the present disclosure is divided into a plurality of first anodes and a plurality of second anodes which are spaced apart from each other, combined with an orthographic projection of a pixel defining layer having at least two long edges and at least two short edges, a length of a printhead nozzle and a length of at least one edge of the pixel defining layer can be equal, so that as many printhead nozzles can participate in a printing process as possible. Therefore, a number of printing times can be reduced, printing time can be prevented from being too long, and a dry Mura problem due to unevenly dried ink at different periods can be prevented. Furthermore, ink printed in the pixel defining layer can flow in the pixel defining layer. As a result, a size of ink in an entire pixel can be uniform, and a thickness of films can be even, thereby effectively preventing line Mura.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which those skilled in the art can derive further figures without making any inventive efforts.

FIG. 1 is a structural schematic view showing a display panel according to one embodiment of the present disclosure.

FIG. 2 is a schematic view showing a pixel defining layer according to one embodiment of the present disclosure.

FIG. 3 is a schematic view showing an anode layer according to one embodiment of the present disclosure.

FIG. 4 is a flowchart showing a manufacturing method according to one embodiment of the present disclosure.

FIGS. 5A to 5D are schematic views showing steps of the manufacturing method according to one embodiment of the present disclosure.

### DETAILED DESCRIPTION

Hereinafter a preferred embodiment of the present disclosure will be described with reference to the accompanying drawings to exemplify the embodiments of the present disclosure can be implemented, which can fully describe the technical contents of the present disclosure to make the technical content of the present disclosure clearer and easy to understand. However, the described embodiments are only some of the embodiments of the present disclosure, but not all of the embodiments. All other embodiments obtained by those skilled in the art based on the embodiments of the present disclosure without creative efforts are within the scope of the present disclosure.

In the description of the present disclosure, it should be understood that terms such as “center”, “longitudinal”, “lateral”, “length”, “width”, “thickness”, “upper”, “lower”, “front”, “rear”, “left”, “right”, “vertical”, “horizontal”, “top”, “bottom”, “inside”, “outside”, “clockwise”, “counter-clockwise”, as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure. In addition, terms such as “first” and “second” are used herein for purposes of description and are not intended to indicate or imply relative importance or significance. Thus, features limited by “first” and “second” are intended to indicate or imply including one or more than one these features. In the description of the present disclosure, “a plurality of” relates to two or more than two, unless otherwise specified.

In conventional display panels, a size of ink dropped in pixels may be overly large or overly small, a printing process takes too much time, and the ink printed at different periods cannot be evenly dried, resulting in Mura problems.

Therefore, an embodiment of the present disclosure provides a display panel and a manufacturing method thereof which are respectively described below in detail.

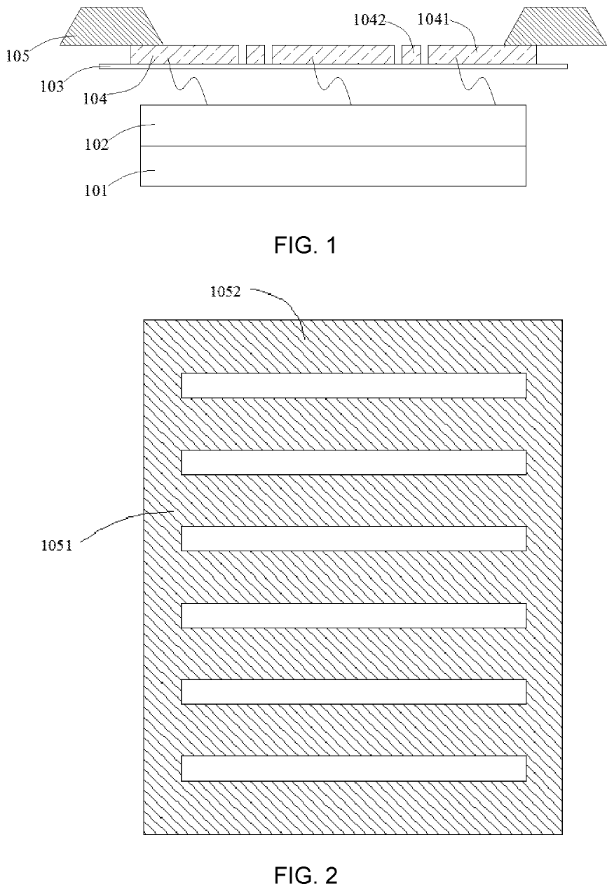

First, the present disclosure provides the display panel. As shown in FIG. 1, a schematic structural view showing the display panel according to the present embodiment is provided. The display panel includes: a first substrate 101, a thin film transistor (TFT) array layer 102 and a planarization layer 103 which are sequentially disposed on a surface of a side the first substrate 101, an anode layer 104 disposed on a surface of a side of the planarization layer 103 away from the TFT array layer 102, and a pixel defining layer 105 disposed on the anode layer 104. A plurality of pixel openings are formed on the anode layer 104. The anode layer 104 includes a plurality of first anodes 1041 and a plurality of second anodes 1042, which are spaced apart from each other.

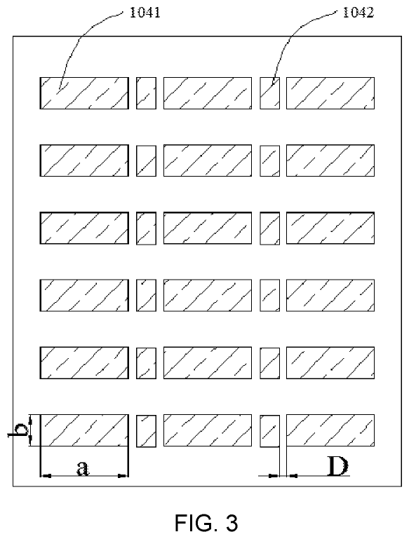

Based on the above embodiment, as shown in FIG. 2, a schematic view showing the pixel defining layer according to the present embodiment is provided. A first orthographic projection of the pixel defining layer 105 on the first substrate 101 includes at least two long edges 1051 and at least two short edges 1052, and each of the short edges 1052 is connected to the at least two long edges 1051.

Compared with conventional display panels, the anode layer 104 of the present disclosure is divided into the first anodes 1041 and the second anodes 1042, which are spaced apart from each other. The first orthographic projection of the pixel defining layer 105 includes at least two long edges 1051 and at least two short edges 1052. The anode layer 104 which different short edges 1052 correspond to is a same sub-pixel. An orthographic projection of each of the at least two short edges 1052 on the anode layer 104 covers the first anodes 1041 and the second anodes 1042, which are spaced apart from each other in a same row, and an orthographic projection of each of the at least two long edges 1051 on the anode layer 104 covers all of the first anodes 1041 in a same column. An objective of patterning the anode layer 104 and the pixel defining layer 105 is to make a length of a printhead nozzle and a length of at least one edge of the pixel defining layer 105 equal, so that as many printhead nozzles can participate in a printing process as possible. If all of the printhead nozzles participate simultaneously in the printing process, the printing process can be finished in one cycle, thereby reducing a number of printing cycles and a printing time, and preventing the dry Mura problem due to ink being disposed at different periods and drying unevenly. Furthermore, ink printed in the pixel defining layer 105 can flow in the pixel defining layer 105. As a result, a size of ink in an entire pixel can be uniform, and a thickness of films can be even, thereby effectively preventing line Mura.

In the above embodiment, areas between the first anodes 1041 and the second anodes 1042 are hollowed out, and there is no substance filled in the hollowed-out area. Preferably, the anode layer 104 can be further optimized. For example, an insulating material 1043 is filled between the first anodes 1041 and the second anodes 1042. More preferably, the insulating material 1043 is acrylic. Because the pixel openings are connected to each other after the pixel defining layer 105 is patterned, different first anodes 1041 are spaced apart from each other to respectively control different sub-pixel areas in the display panel. In addition, the insulating material 1403 filled between the first anodes 1041 and the second anodes 1042 can prevent short circuiting.

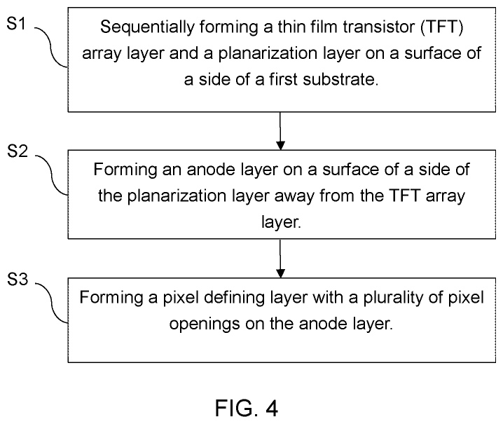

As shown in FIG. 3, a schematic view showing the anode layer according to the present embodiment is provided. The second anodes 1042 are dummy anode areas. A distance between the first anodes 1041 and the second anodes 1042 is D, a length of the long edges of the first anodes 1041 is a, and a length of the short edges of the first anodes 1041 is b. Preferably, the distance D ranges from 2 μm to 10 μm, the length a ranges from 100 μm to 200 μm, and the length b ranges from 20 μm to 80 μm. More preferably, the distance D is 5 μm, the length a is 150 μm, and the length b is 50 μm.

In another embodiment, the first orthographic projection of the pixel defining layer 105 on the first substrate 101 overlaps with at least a portion of a second orthographic projection of the anode layer 104 on the first substrate 101. A sectional view of the pixel defining layer 105 is trapezoidal and includes a narrow top and a wide bottom. The pixel defining layer 105 and the overlapped area form a notch structure configured to contain ink.

Preferably, the anode layer 104 includes a hydrophilic material, or a hydrophilic thin film is disposed on the anode layer 104. Wherein, a main material of the anode layer 104 is indium tin oxide (ITO). To further optimize hydrophilicity of the anode layer 104, powders of the hydrophilic material can be doped into the anode layer 104. Alternatively, the hydrophilic thin film can be disposed on a side of the anode layer 104 near the pixel defining layer 105. Therefore, the first anodes 1041 and the second anodes 1042 can help ink flow in the pixel defining layer 105, leading to a uniform size of ink droplets and even thickness of films in the entire pixel.

In the present embodiment, the display panel further includes an organic light-emitting diode (OLED) device including an anode layer, a hole injection layer, a hole transport layer, a luminescent layer, and a cathode layer.

To better obtain the display panel mentioned in the present embodiment, a manufacturing method of the above display panel is further provided.

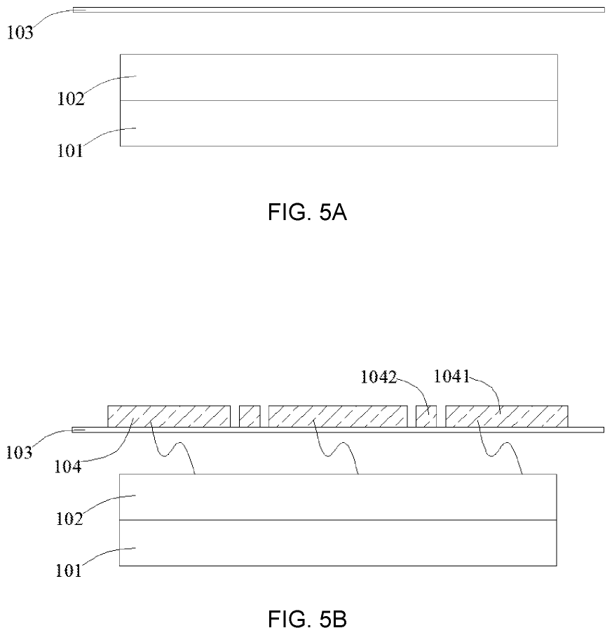

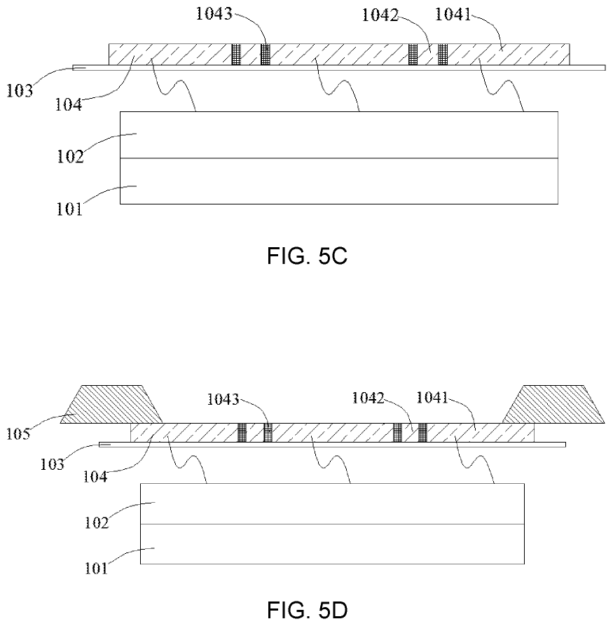

As shown in FIG. 4 and FIGS. 5A to 5D, a flowchart showing the manufacturing method according to the present embodiment and schematic views showing steps of the manufacturing method according to the present embodiment are provided. The manufacturing method includes following steps:

S1: sequentially forming a thin film transistor (TFT) array layer 102 and a planarization layer 103 on a surface of a side of a first substrate 101.

Specifically, as shown in FIG. 5A. The TFT array layer 102 includes a low temperature poly-silicon (LTPS) device and an indium gallium zinc oxide (IGZO) device.

S2: forming an anode layer 104 on a surface of a side of the planarization layer 103 away from the TFT array layer 102.

Specifically, as shown in FIG. 5B. The anode layer 104 is manufactured by coating, exposure, development, etching, and demolding processes. The anode layer 104 includes a plurality of first anodes 1041 and a plurality of second anodes 1042, and the second anodes 1042 are dummy anodes.

S3: forming a pixel defining layer 105 with a plurality of pixel openings on the anode layer 104.

Specifically, please refer to FIG. 1.

Preferably, there is a step performed after the step S2, yet before the step S3 comprising: filling an insulating material 1043 between the first anodes 1041 and the second anodes 1042, specifically, as shown in FIG. 5C and FIG. 5D.

Preferably, there is a step performed after the step S3 comprising: forming a hole injection layer, a hole transport layer, a luminescent layer, and a cathode layer on the anode layer 104, and then encapsulating the above layers to form an organic light-emitting diode (OLED) device.

In the above embodiments, the focus of each embodiment is different, and for a part that is not detailed in an embodiment, reference may be made to related descriptions of other embodiments. In specific implementations, each of the above units or structures may be implemented independently or may be combined as one, several entities, or any combination to realize the present disclosure. Implementations of each of the above units or structures may be understood with reference to the above embodiments and will not be described again here. Specific applications may be referred to the above embodiments, and are not described here.

The above embodiments of the present disclosure have been described in detail, which illustrates principles and implementations thereof. However, the description of the above embodiments is only for helping to understand the technical solution of the present disclosure and core ideas thereof, and it is understood by those skilled in the art that many changes and modifications to the described embodiment can be carried out without departing from the scope and the spirit of the disclosure that is intended to be limited only by the appended claims.

1. A display panel, comprising
a first substrate;
a thin film transistor (TFT) array layer and a planarization layer which are sequentially disposed on a surface of a side of the first substrate;
an anode layer disposed on a surface of a side of the planarization layer away from the TFT array layer; and
a pixel defining layer, wherein a plurality of pixel openings are formed on the anode layer;
wherein the anode layer comprises a plurality of first anodes and a plurality of second anodes, which are spaced apart from each other.

2. The display panel of claim 1, wherein an insulating material is filled between the first anodes and the second anodes.

3. The display panel of claim 1, wherein a distance between the first anodes and the second anodes ranges from 2 μm to 10 μm.

4. The display panel of claim 1, wherein a sectional view of the first anodes are rectangular, a length of long edges of the first anodes ranges from 100 μm to 200 μm, and a length of short edges of the first anodes ranges from 20 μm to 80 μm.

5. The display panel of claim 1, wherein a first orthographic projection of the pixel defining layer on the first substrate comprises at least two long edges and at least two short edges, and each of the short edges is connected to the at least two long edges.

6. The display panel of claim 1, wherein a first orthographic projection of the pixel defining layer on the first substrate overlaps with at least a portion of a second orthographic projection of the anode layer on the first substrate.

7. The display panel of claim 1, wherein the anode layer comprises a hydrophilic material, or a hydrophilic thin film is disposed on the anode layer.

8. The display panel of claim 1, wherein the display panel further comprises an organic light-emitting diode (OLED) device comprising an anode layer, a hole injection layer, a hole transport layer, a luminescent layer, and a cathode layer.

9. The display panel of claim 1, wherein a sectional view of the pixel defining layer is trapezoidal and has a narrow top and a wide bottom.

10. A method of manufacturing a display panel, comprising following steps:
sequentially forming a thin film transistor array (TFT) layer and a planarization layer on a surface of a side of a first substrate;
forming an anode layer on a surface of a side of the planarization layer away from the TFT array layer; and
forming a pixel defining layer with a plurality of pixel openings on the anode layer.

11. The method of claim 10, wherein the anode layer comprises a plurality of first anodes and a plurality of second anodes, which are spaced apart from each other.

12. The method of claim 10, wherein an insulating material is filled between the first anodes and the second anodes.

13. The method of claim 11, wherein a distance between the first anodes and the second anodes ranges from 2 μm to 10 μm.

14. The method of claim 11, wherein a sectional view of the first anodes is rectangular, a length of long edges of the first anodes ranges from 100 μm to 200 μm, and a length of short edges of the first anodes ranges from 20 μm to 80 μm.

15. The method of claim 10, wherein a first orthographic projection of the pixel defining layer on the first substrate comprises at least two long edges and at least two short edges, and each of the short edges is connected to the at least two long edges.

16. The method of claim 10, wherein a first orthographic projection of the pixel defining layer on the first substrate overlaps with at least a portion of a second orthographic projection of the anode layer on the first substrate.

17. The method of claim 10, wherein the anode layer comprises a hydrophilic material, or a hydrophilic thin film is disposed on the anode layer.

18. The method of claim 10, wherein the display panel further comprises an organic light-emitting diode (OLED) device comprising the anode layer, a hole injection layer, a hole transport layer, a luminescent layer, and a cathode layer.

19. The method of claim 10, wherein a sectional view of the pixel defining layer is trapezoidal and has a narrow top and a wide bottom.
